(19) United States
(12) Patent Application Publication
(10) Pub. No.: US 2005/0214456 A1
(43) Pub. Date: Sep. 29, 2005

(54) Enhanced dielectric layers using sequential deposition

(76) Inventor: Donghul Lu, San Jose, CA (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 10/811,591

(22) Filed: Mar. 29, 2004

(51) Int. Cl. C23C 16/00

(52) U.S. Cl. 427/248.1; 427/569

(57) ABSTRACT

A dielectric layer may be formed for semiconductor devices using sequential deposition processes. In one embodiment, such a layer may be formed by applying plasma power to a plasma enhanced sequential chemical vapor deposition chamber, introducing a deposition gas after applying the plasma power, starting nitride deposition in the chamber to form a first portion of a layer on a substrate, and turning off the plasma power. Multiple portions of a layer may be formed by repeating these operations.

### BACKGROUND

1. Field

Embodiments of the present invention relates to the field of semiconductor fabrication and, in particular, to producing silicon nitride films using sequential deposition platforms.

2. Background

Silicon nitride film is widely used as etch stop layer and passivation layer on IC (integrated circuit) products, such as logic microprocessors, DRAM (dynamic random access memory), and non-volatile flash memories. Silicon nitride films can be formed using PECVD (Plasma Enhanced Chemical Vapor Deposition) on a sequential deposition platform.

In many such platforms, a single deposition plasma chamber has more than 1 parallel plate deposition source. One silicon device wafer sits beneath each of the showerheads. Each showerhead deposits part of the total target silicon nitride layer thickness (i.e., ¼ of total thickness if there are 4 showerheads, and ⅙ of total thickness if there are 6 showerheads). After deposition at one showerhead, the wafers are rotated to another showerhead for another deposition cycle. The plasma is turned off in between deposition cycles while the wafers are being rotated.

In an alternative sequential deposition design, several different chambers are used and a robot arm moves wafers from one chamber to the next in between cycles. Each chamber deposits portions of total target thickness.

Sequentially deposited silicon nitride films in conventional methods have intra-film compositional interfaces due to interactions between gas flow and plasma initiation. These compositional interfaces are usually silicon rich and provide significant electrical leakage paths, and even points of origin for catastrophic and explosive dielectric breakdowns.

The intra-film interfaces reduce the resulting semiconductor device's ability to withstand high electric fields commonly used during, for example, flash memory program and erase cycles. The interfaces also require significantly wider flash memory cell contact-gate spacing in order to reduce the likelihood of a dielectric breakdown, increasing the size and cost of the system.

### BRIEF DESCRIPTION OF THE DRAWINGS

Embodiments of the present invention will be understood more fully from the detailed description given below and from the accompanying drawings of various embodiments of the invention. The drawings, however, should not be taken to be limiting, but are for explanation and understanding only.

FIG. 1 is a cross-sectional diagram of a flash memory transistor wrapped around by a silicon nitride etch stop layer formed through sequential deposition process;

FIG. 2A is a diagram of a sequential deposition silicon nitride layer having intra-film interfaces;

FIG. 2B is a diagram of a sequential deposition silicon nitride layer produced in accordance with an embodiment of the present invention;

FIG. 3 is a block diagram of a sequential deposition PECVD chamber;

FIG. 4 is a process flow diagram of sequential deposition of a silicon nitride layer according to one embodiment of the invention;

FIG. 5 is a block diagram of a computing system suitable for implementing an embodiment of the present invention.

### DETAILED DESCRIPTION

Embodiments of the present invention relate to preparing silicon nitride (Si₃N₄) or silicion oxynitride (SiON) layers by sequential deposition, using for example, PECVD (plasma enhanced chemical vapor deposition) platforms. The layers show fewer defects, improved reliability and significant improvement in dielectric properties, yield, and reliability performance. The layers also allow for aggressive contact-gate scaling by, in one example, up to 20 nm in 90 nm node flash technologies without a significant increase in failures caused by nitride dielectric breakdown. Films formed according to embodiments of the present invention may be used as etch stop layers for ULC (unlanded contacts) patterning on flash memory products, which usually have the highest electric field. There are many other uses for silicon nitride or oxynitride films formed according to embodiments of the present invention, such as nitride spacers, nitride capacitors, nitride passivation layers, nitride dielectrics in ONO (Oxide/Nitride/Oxide) structures, via etch stop layers in copper damascene backend technologies and many others.

A significant benefit of some embodiments of the present invention is the elimination of intra-film compositional interfaces often caused from sequential deposition. These interfaces are common and characteristic of conventional sequentially deposited film and may be experimentally verified to be significant electrical leakage paths and origins of catastrophic dielectric breakdown.

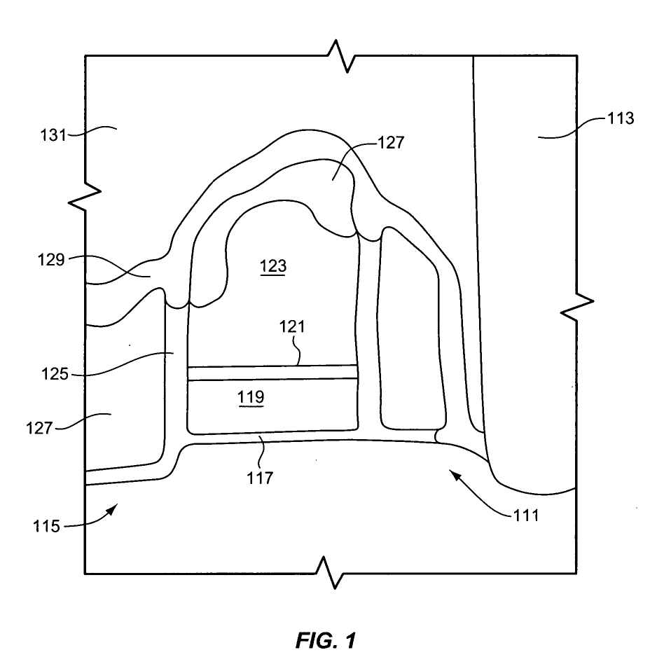

FIG. 1 shows an example of a flash memory transistor suitable for embodiments of the present invention. While a flash memory transistor is shown, embodiments of the invention may be applied to many different types of devices, such as logic microprocessors, DRAM, and other non-volatile memory architectures as well as to many different types of systems, such as flash, ROM, EPROM, controllers and microprocessors. The illustrated transistor has a drain area 111 closest to the bottom substrate on which the transistor has been formed and to one side of the gates. A tungsten probe 113 provides an electrical connection to the drain for circuitry above the transistor. On the opposite side of the gates and closest to the bottom substrate is a source area 115. Above the source and drain is a gate dielectric layer 117, such as a silicon dioxide (SiO₂ ) or similar tunnel oxide layer and a floating gate 119 above the gate oxide layer. The floating gate may be formed of polysilicon or any other appropriate material.

A dielectric layer 121 is formed above the floating gate to separate the floating gate from a polysilicon control gate 123. The dielectric layer may be formed from many different materials including an oxide/nitride/oxide composition. A dielectric liner 125, such as SiO₂ is formed on either side of the two gates to insulate the sides of the floating and contact gate. Outside the dielectric layer is a nitride spacer layer 127.

Above the gates, cobalt silicide formations 127 are grown around the top of the control gate and an etch stop silicon nitride (Si₃N₄) layer 129 is formed to cover the entire transistor structure. The silicon nitride layer covers the cobalt silicide formations, the control and floating gates, the liner oxide, and the nitride spacers. After the transistor structure has been etched and cleaned, an inter-layer dielectric layer 131 covers the entire structure.

The silicon nitride layer may be formed using sequential plasma enhanced chemical vapor deposition. However, as described above, such sequentially deposited layer may have poor dielectric interfaces between each layer and poor bulk dielectric properties. When such a transistor is exposed to high operating voltages, the silicon nitride layer may break down, destroying the transistor.

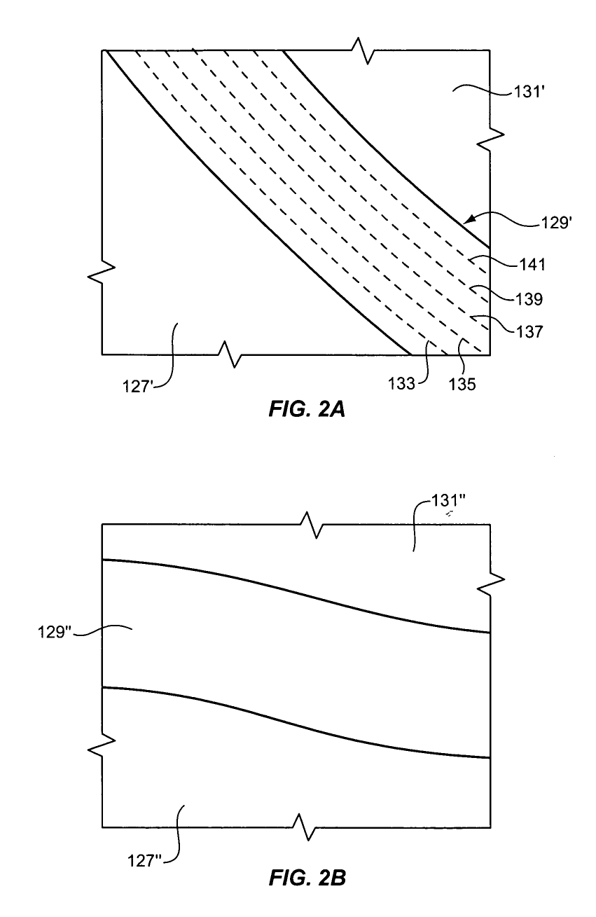

FIG. 2A shows a nitride layer 129′ between a silicon nitride spacer layer 127′ and an inter-layer dielectric 131′ in a structure similar to that shown, for example in FIG. 1. The nitride layer includes five separate intra-film interfaces 133, 135, 137, 139, and 141. The interfaces are in between each sequentially deposited nitride sublayer. In FIG. 2B, a nitride layer 129″ is formed according to an embodiment of the invention so that no intra-film interfaces are found. As with FIG. 2A, the nitride layer has a silicon nitride spacer layer 127″ on one side and an intra-layer dielectric 131″ on the other.

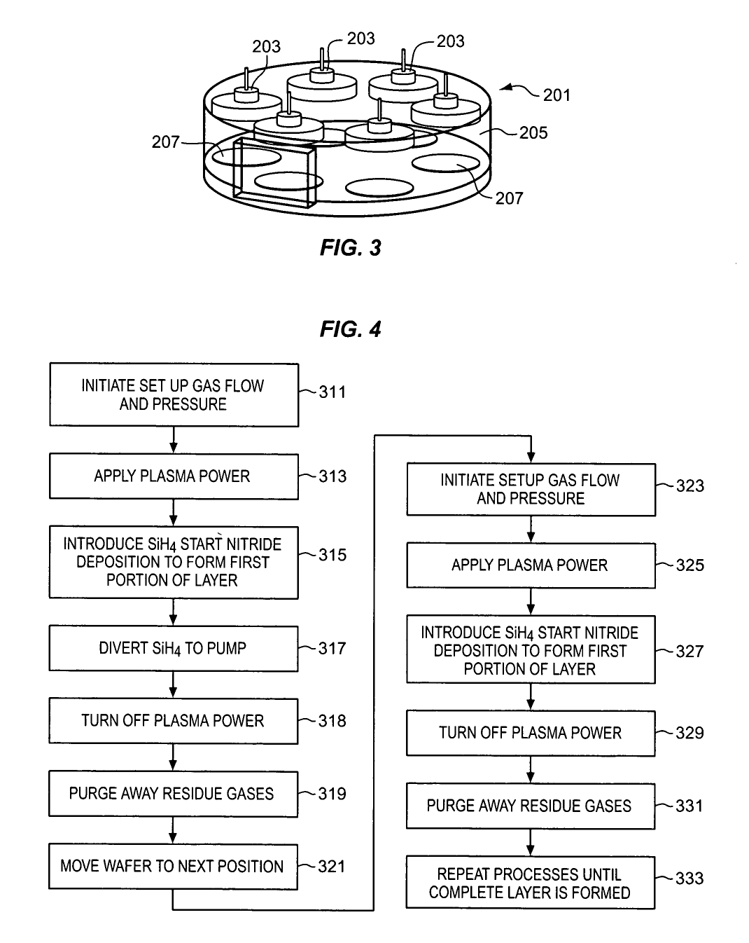

As shown in FIG. 3, a conventional sequential deposition PECVD chamber 201 has a plurality of showerheads 203 within the chamber interior 205 for providing the appropriate chemical vapor (e.g. SiH₄/NH₃) for deposition. A showerhead is suspended over each of six different wafers 207. One such PECVD chamber is the Novellus 200 mm PECVD Sequel platform. This platform has a single-chamber 6-showerhead sequential deposition design. Each showerhead deposits ⅙ of the total target thickness, and the wafers are then rotated to the next showerhead for the next deposition sequence. An alternative type of platform uses six different subchambers or portions of chambers and the wafers are moved from one chamber to the next to produce the single layer in six different operations.

In sequential deposition processes, the plasma is turned off during wafer rotations between showerheads or deposition chambers. This may result in a final completed nitride or oxynitride film with multiple intra-film interfaces, as shown in FIG. 2A. The interfaces represent compositional discontinuities at the beginning of each deposition sequence when the plasma is turned on.

In one embodiment, using such a showerhead sequential deposition process, a nitride (Si₃N₄), oxynitride (SiON) or other layer may be deposited in accordance with the parameters listed below. These parameters have been tested as being effective for a particular type of wafer in a particular type and condition of equipment in order to achieve a certain type of NESL (nitride etch stop layer). Many of the parameters provided above may require some variation with different wafers, different nitrides, different application of the nitride layer (e.g. etch stop and other types) and different equipment, among other possible process variations and applications.

| | |
|---|---|
| Set up gas flow - SiH₄/NH₃ ratio | 1:20-1:30 |
| Gas Flow Rate - SiH₄/NH₃/N₂ | 180-220/4500-5500/1500-1800 sccm |
| Set up pressure | 1.8-2.5 torr |
| Timing between SiH₄ introduction | SiH₄ late by 0.5 to 1 second |
| and RF turn-on | |
| Plasma Power condition | 500 ± 25 W/200 ± 25 W |
| (HFRF/LFRF) | |
| Deposition Rate | 600-800 A/min |
| Refractive Index | 1.88 to 1.92 |
| Film resistivity (ohm · cm) | >1e¹⁶ |
| H bonding status (Si—H/N—H) | <1:9 |
| (total H equivalent) | |
| Tunneling field (MV/cm) | >10 |
| Breakdown Field (MV/cm) | >10 |

Most conventional nitride processes have a relatively high silane/ammonia (SiH₄/NH3) ratio to accommodate a targeted stoichiometrical silicon nitride refractive index of, for example, 2.0. During initial stages of plasma ignition, a silicon rich interface will form between each sequential deposition operation since silane breaks down more easily in a plasma environments and is much more reactive than ammonia precursors. Silicon-rich interfaces, however, act as leakage paths. In addition, PECVD nitride with a refractive index of 2.0 may also have high concentrations of silicon-hydrogen bonds, which may degrade dielectric properties.

During flash memory program/erase cycles (where voltage bias may be more than 15V between controlling gate and drain contact), conventional silicon nitrides between the controlling gate and drain contact (such as ULC nitride) may not be able to withstand high contact-gate electrical fields and experience explosive breakdown. ULC dielectric properties therefore become a limiter for contact-gate distance scaling for future generations of flash technology.

The parameters shown above may be applied in a process as represented by FIG. 4. In FIG. 4, set up gas flow and pressure is initiated at block 311. The set-up gases may be ammonia and nitrogen and may include other or different gases as desired. The silane gas is diverted to the chamber's gas pump or kept out of the chamber in some other way. The RF plasma power is applied at block 313. At block 315, silane is introduced into the chamber by, for example, stopping the diversion to the pump. In the example above, silane is introduced 0.5 seconds after the RF plasma power is applied. Nitride deposition starts to form the first portion of the nitride or oxynitride or other layer as soon as silane is introduced. At block 317, silane is diverted from the chamber, and after 0.5 seconds or longer the plasma power is turned off at block 318. At block 319, residue gases in the chamber are purged out to the pump. This completes the first portion of the sequential layer formation. The wafer may then be moved to the next showerhead or subchamber at block 321. This may involve moving the wafer, moving equipment that was acting on the wafer, or both.

After the wafer is moved to the next position, the sequence of deposition operations may be repeated to form a second portion of the layer. As mentioned above, this may be in the same or a different location as for the first layer. At block 323, the ammonia/nitrogen gas flow and pressure are re-established. At block 325 the plasma power is applied. At block 327, the silane is re-introduced and the nitride deposition is started to form the second portion of the layer.

After the second portion is formed, the silane flow is diverted from the chamber at block 328, and, after 0.5 seconds or longer, the plasma is turned off at block 329. At block 331, residue gases in the chamber are purged out to the pump again. The wafer may then be moved again and the sequence may be continued at block 333 until the complete layer is formed.

In the process described above, silane flow may be reduced significantly and the silane/ammonia flow ratio may be optimized to the best dielectric properties using metal-insulator-silicon characterization. In addition, during each deposition sequence, silane may be introduced to the chamber 0.5 to 1 seconds after plasma is ignited with ammonia and other carrier gases. The low silane flow, optimized silane/ammonia ratio, and plasma timing may provide an elimination of intra-film silicon-rich interfaces that are common in sequential deposition. It may also result in a dramatic reduction in Si—H concentration in the bulk film, a 10× film resistivity improvement, and a 2× improvement in tunneling strength.

According to some embodiments of the present invention, defects are reduced by over 30% compared to nitride processes with intra-film interfaces. These embodiments are more effective at suppressing nucleation sites for defect formation and growth over the spacer and salicide stacks and therefore lead to considerably lower defect densities.

Embodiments of the present invention may be applied to many sequential deposition platforms, not limited to 200 mm sizes (i.e., applicable to 150 mm, 300 mm, 450 mm etc. sizes). This may enable more aggressive contact-gate spacing on flash cells and result in smaller cell sizes in 90 nm node and later technologies.

With a process as described above, intra-film compositional variations may be eliminated, resulting in a uniform nitride composition across the film thickness. In addition, the dielectric strength may be improved by more than 4×, the resistivity improved by 10×, and the leakage reduced by 1000×. In addition, trials have shown a 30% defect density reduction, verified in high volume manufacturing sites on all specific flash products, together with a yield improvement by 15 non-redundant ISO points (pre-repair) at sort 1 (pre-repair, pre-bake testing) and 30 non-redundant ISO points at sort 2 (post-bake). There may also be a reduction by more than 1000 dpm (die per million) in infant cycling failures during reliability cycling reliability testing.

Embodiments of the present invention may also be applied to obtain a SIMS (Secondary Ion Mass Spectroscopy) compositional depth profile of nitride films deposited either as a blanket layer or on commercial devices. Whereas, many films generate SIMS profiles with fluctuations in Si and SiN traces that correspond to the intra-film interfaces discussed above, embodiments of the present invention may eliminate these irregularities and consequently produce smooth, uniform SIMS profiles without the fluctuations.

Integrated circuits containing the nitride layers disclosed herein may be incorporated in various forms of electrical systems including computer systems (e.g., portable, laptop, desktop, server, mainframe, etc.).

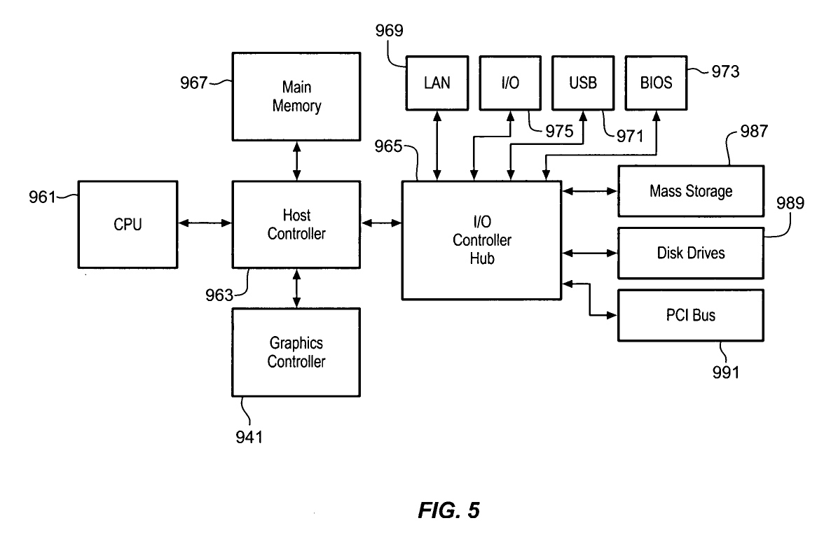

FIG. 5 shows a computer system suitable for use with a flash memory chip formed as described above. While embodiments of the present invention may be adapted for application on a great number of different ICs, the present example is described in the context of a flash memory BIOS (Basic Input/Output System) chip that supports a microprocessor through an I/O controller hub and a host controller. In this example, the computer system may include a CPU (Central Processing Unit) 961 coupled to a Host Controller 963, for example a Memory Controller Hub (MCH) chip. The MCH chip functions as part of a supporting chipset for the CPU. The MCH chip is coupled to main memory 967, such as DRAM and to a graphics controller 941.

The MCH chip 963 is also coupled to an ICH (Input/Output controller hub) chip 965. The ICH chip offers connectivity to a wide range of different devices. Well-established conventions and protocols may be used for these connections. The connections may include a LAN (Local Area Network) port 69, a USB hub 971, and the local BIOS (Basic Input/Output System) flash memory 973. A SIO (Super Input/Output) port 975 may provide connectivity for a keyboard or other input devices.

The ICH may also provide an IDE (Integrated Device Electronics) bus for connections to disk drives 987, 989 or other large memory devices. The mass storage may include hard disk drives and optical drives. So, for example, software programs, user data, and data files may be stored on a hard disk drive or other drive. In addition CD's (Compact Disk), DVD's (Digital Versatile Disk) and other storage media may be played on drives coupled to the IDE bus.

A PCI (Peripheral Component Interconnect) bus 991 is coupled to the ICH and allows a wide range of devices and ports to be coupled to the ICH, such as network and video adapter cards. There are many more devices available for connection to a PCI port and many more possible functions. The PCI devices may also allow for wired or wireless connections to more remote equipment or any of a number of different interfaces. The remote equipment may allow for communication of programming data, for maintenance or remote control or for gaming, Internet surfing or other capabilities.

It is to be appreciated that a lesser or more equipped semiconductor device, flash memory transistor, chip, and computer system than the examples described above may be preferred for certain implementations. Therefore, the configurations may vary from implementation to implementation depending upon numerous factors, such as price constraints, performance requirements, technological improvements, or other circumstances. Embodiments of the invention may also be applied to other types of systems that use different devices than those shown in the Figures.

In the description above, numerous specific details are set forth. However, it is understood that embodiments of the invention may be practiced without these specific details. For example, well-known equivalent materials may be substituted in place of those described herein, and similarly, well-known equivalent techniques may be substituted in place of the particular processing techniques disclosed. In other instances, well-known circuits, structures and techniques have not been shown in detail to avoid obscuring the understanding of this description.

While the embodiments of the invention have been described in terms of several embodiments, those skilled in the art will recognize that the invention is not limited to the embodiments described, but may be practiced with modification and alteration within the spirit and scope of the appended claims. The description is thus to be regarded as illustrative instead of limiting.

1. A method comprising:
applying plasma power to a plasma enhanced sequential chemical vapor deposition chamber;
introducing a deposition gas after applying the plasma power;
starting nitride deposition in the chamber to form a first portion of a layer on a substrate; and
turning off the plasma power.

2. The method of claim 1, further comprising:
reapplying plasma power;
reintroducing a deposition gas after reapplying the plasma power;
starting nitride deposition in the chamber to form a second portion of the layer on the substrate after reapplying the plasma power; and
turning off the plasma power.

3. The method of claim 2, wherein introducing a deposition gas comprises introducing silane gas.

4. The method of claim 2, wherein introducing silane gas comprises introducing silane gas at least 0.5 seconds after applying plasma power.

5. The method of claim 2, wherein introducing silane gas comprises diverting silane gas from a pump to the deposition chamber.

6. The method of claim 1, further comprising initiating set up gas flow and pressure in the chamber before applying the plasma power.

7. The method of claim 6, wherein initiating set-up gas flow comprises flowing ammonia and nitrogen gases into the chamber.

8. The method of claim 1, further comprising pumping away residue gases after turning off the plasma power and before reapplying the plasma power.

9. The method of claim 1, further comprising moving a first nitride supply fixture to form the first portion of the layer away from the wafer and moving a second nitride supply fixture to form the second portion of the layer to the wafer after forming the first portion of the layer and before forming the second portion of the layer.

10. The method of claim 1, further comprising moving the wafer to another chemical vapor deposition position after forming the first portion of the layer and before forming the second portion of the layer.

11. The method of claim 1, further comprising repeating turning on and off the nitride supply and the plasma power substantially simultaneously until a complete layer is formed.

12. A semiconductor device having a layer formed in accordance with the method of claim 1.

13. The semiconductor device of claim 12 wherein the layer is a nitride etch stop layer.

14. A semiconductor device comprising a layer formed by sequential chemical vapor deposition, the layer having no intra-film interfaces corresponding to transitions of the sequential chemical vapor deposition formation.

15. The semiconductor device of claim 14 wherein the layer is a nitride etch stop layer.

16. The semiconductor device of claim 14 wherein the layer is a silicon nitride layer.

17. The semiconductor device of claim 14 wherein the layer is an insulating layer for a gate of a flash memory transistor.

18. A semiconductor device comprising:
a drain area;
a source area;
a gate layer coupled to the drain area and the source area;
a sequential deposition nitride layer overlying the gate layer, the nitride layer having no intra-film interfaces corresponding to transitions of the sequential deposition.

19. The semiconductor device of claim 18 wherein the layer is a nitride etch stop layer.

20. The semiconductor device of claim 18 wherein the layer is an insulating layer for a gate of a flash memory transistor.
